(19) United States
(12) Patent Application Publication
(10) Pub. No.: US 2025/0132266 A1
(43) Pub. Date: Apr. 24, 2025

(54) METHOD OF MANUFACTURING SEMICONDUCTOR PACKAGE STRUCTURE AND SEMICONDUCTOR PACKAGE STRUCTURE

(71) Applicant: Universal Global Technology(Shanghai)Co.,Ltd., Shanghai (CN)

(72) Inventors: Yao LI, Shanghai (CN); Wenwen LI, Shanghai (CN); Lin WANG, Shanghai (CN)

(73) Assignee: Universal Global Technology(Shanghai)Co.,Ltd., Shanghai (CN)

(21) Appl. No.: 18/916,741

(22) Filed: Oct. 16, 2024

(30) Foreign Application Priority Data
Oct. 20, 2023 (CN) 202311371555.2

(51) Int. Cl. H01L 23/552; H01L 21/48; H01L 21/56; H01L 21/768; H01L 23/00; H01L 23/29; H01L 23/31; H01L 25/065

(52) U.S. Cl. CPC H01L 23/552; H01L 21/4846; H01L 21/56; H01L 21/76877; H01L 23/293; H01L 23/3121; H01L 24/08; H01L 25/0655; H01L 2224/08225; H01L 2924/1815

(57) ABSTRACT

A semiconductor package structure and a method of manufacturing the same are provided. The method includes: providing a substrate having a mounting surface and at least one grounding pad; mounting a semiconductor device onto the mounting surface; mounting at least a metal piece onto the mounting surface, wherein the metal piece is electrically connected to the grounding pad; forming a plastic package body, which covers the semiconductor device and the metal piece; forming an electromagnetic shielding layer, which covers the plastic package body and side surfaces of the substrate; exposing a surface of the metal piece; and attaching a grounding body to the surface of the metal piece through soldering. The semiconductor package structure and the method of manufacturing the same achieve high connection strength and high corrosion-resistance between the grounding body in the semiconductor package structure and the grounding pad of the substrate.

### CROSS-REFERENCE TO THE RELATED APPLICATIONS

This application is based upon and claims priority to Chinese Patent Application No. 202311371555.2, filed on Oct. 20, 2023, the entire contents of which are incorporated herein by reference.

### TECHNICAL FIELD

The present application relates to a field of chip packaging technology, and specifically relates to a manufacturing method of a semiconductor package structure and a semiconductor package structure.

### BACKGROUND

A main function of grounding is to ensure the safety and stability of a circuit and to suppress electromagnetic interferences. In order to improve performance and reliability of an electronic component, grounding technology is widely used in the semiconductor manufacturing processes.

In system-level packaging of a wearable device, a common grounding method is sticking a grounding body, such as metal spring, metal sheet, or metal wire, or the like, to a surface of an electromagnetic shielding layer through a copper foil tape, and then forming a complete connection to a grounding layer of a substrate through the electromagnetic shielding layer. However, this connection manner for grounding is not firm and is easily corroded.

### SUMMARY

An object of the present application is to provide a manufacturing method of a semiconductor package structure and a semiconductor package structure to solve a problem of unfirm connection between a grounding body and a grounding layer of a substrate in a current semiconductor package structure.

A technical solution provided by the present application is as follows:

A method of manufacturing a semiconductor package structure, including:
providing a substrate having a mounting surface and at least one grounding pad;
mounting a semiconductor device onto the mounting surface;
mounting at least one metal piece onto the mounting surface, wherein the metal piece is electrically connected to the grounding pad;
forming a plastic package body that covers the semiconductor device and the metal piece;
forming an electromagnetic shielding layer that covers the plastic package body and side surfaces of the substrate;
exposing a surface of the metal piece;
mounting a grounding body to the surface of the metal piece through soldering technology.

In some embodiments, the method includes:
grooving above the metal piece to remove a part, that is above the metal piece, of the plastic package body and a part, that is above the metal piece, of the electromagnetic shielding layer, to expose the surface of the metal piece.

In some embodiments, the method includes:
after forming the plastic package body and before forming the electromagnetic shielding layer, grooving above the metal piece to remove a plastic package layer above the metal piece to expose the surface of the metal piece;
forming an electromagnetic shielding layer that covers the plastic package body, the surface of the metal piece and the side surfaces of the substrate;
removing the part, covering the surface of the metal piece, of the electromagnetic shielding layer to expose the surface of the metal piece.

In some embodiments, the metal piece is a shielding device used for electromagnetic shielding.

In some embodiments, the electromagnetic shielding layer is formed by sputtering, spraying, electroplating, or coating.

In some embodiments, the part of the plastic package body and/or the part of the electromagnetic shielding layer is removed by laser, etching, or drilling.

The present application further provides a method of manufacturing a semiconductor package structure, including:
providing a substrate having a mounting surface and at least one grounding pad;
mounting a plurality of semiconductor devices onto the mounting surface;
forming a plastic package body that covers the semiconductor devices;
forming a groove on the plastic package body between the semiconductor devices;
filling the groove with conductive material to form a conductive structure;
forming an electromagnetic shielding layer that covers the plastic package body, a surface of the conductive structure, and side surfaces of the substrate;
exposing the conductive material of the conductive structure;
mounting a grounding body to a surface of the conductive material through soldering technology.

In some embodiments, the conductive material is exposed by grooving above the conductive structure to remove a part, that is above the surface of the conductive material, of the electromagnetic shielding layer.

The present application further provides a semiconductor package structure, including:
a substrate, having a mounting surface and at least one grounding pad;
a semiconductor device, mounted on the mounting surface;
a metal piece, mounted on the mounting surface, wherein the metal piece is electrically connected to the grounding pad;
a plastic package body, configured to cover the semiconductor device and the metal piece except for a surface of the metal piece;
an electromagnetic shielding layer, configured to cover the plastic package body and side surfaces of the substrate;
a grounding body, mounted to the surface of the metal piece through soldering technology.

The present application further provides a semiconductor package structure, including:
a substrate, having a mounting surface and at least one grounding pad;
a plurality of semiconductor devices, mounted onto the mounting surface;
a plastic package body, configured to cover the semiconductor devices;
a conductive structure, filled with conductive material, located between the semiconductor devices, and electrically connected to the grounding pad;
an electromagnetic shielding layer, configured to cover the plastic package body and side surfaces of the substrate;
a grounding body, mounted to a surface of the conductive material through soldering technology.

The method of manufacturing a semiconductor package structure and the semiconductor package structure provided by the present application can at least bring about the following beneficial effects: the grounding body in the semiconductor package structure is connected to the metal piece or the conductive material of the conductive structure through soldering, thereby enhancing strength of a connection between the grounding body and the grounding pad of the substrate, and improving corrosion resistance of the connection.

### BRIEF DESCRIPTION OF THE DRAWINGS

Some embodiments will be described below in a clear and easy-to-understand manner with reference to accompanying drawings, and the above-mentioned characteristics, technical features, advantages and implementation of the method of manufacturing a semiconductor package structure and the semiconductor package structure will be further described.

FIG. 1 is a flow chart of a method of manufacturing a semiconductor package structure according to an embodiment of the present application;

FIG. 2 is a flow chart of a method of manufacturing a semiconductor package structure according to another embodiment of the present application;

FIG. 3 is a flow chart of a method of manufacturing a semiconductor package structure according to another embodiment of the present application;

FIGS. 4-6 are schematic cross-sectional views of a semiconductor package structure obtained at different stages according to the method of manufacturing a semiconductor package structure shown in FIG. 1;

FIGS. 7-9 are schematic cross-sectional views of a semiconductor package structure obtained at different stages according to the method of manufacturing a semiconductor package structure shown in FIG. 3.

### DETAILED DESCRIPTION OF THE EMBODIMENTS

In order to explain technical solutions in the embodiments of the present application or in the prior art more clearly, some implementations of the present application will be described below with reference to the accompanying drawings. Obviously, the drawings in the following description are only some embodiments of the present application. For those of ordinary skill in the art, without exerting creative efforts, other drawings can also be obtained based on these drawings, so as to obtain other embodiments.

In order to keep the drawings concise, only the parts related to the present application are schematically shown in each figure, and they do not represent the actual structure of a product. In addition, in order to make the drawings concise and easy to understand, in some drawings, only one of the components having the same structure or function is schematically drawn or labeled. In this article, “a” not only means “only one”, but can also mean “more than one”.

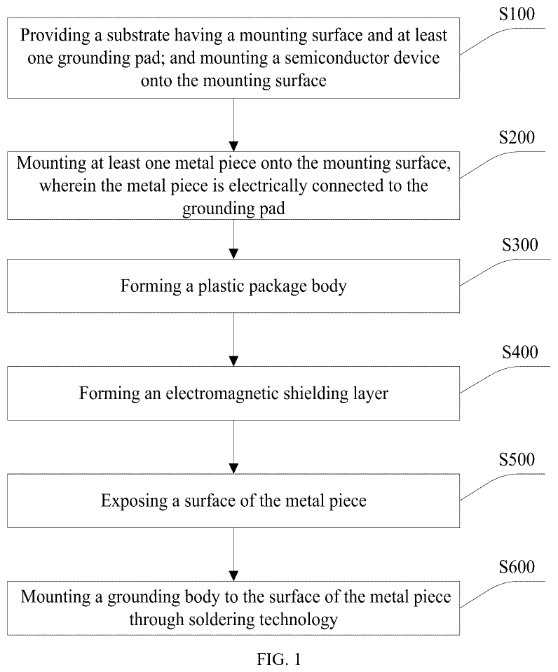

In one embodiment of the present application, as shown in FIG. 1, a method of manufacturing a semiconductor package structure includes:
step S100, providing a substrate having a mounting surface and at least one grounding pad;
and mounting a semiconductor device onto the mounting surface;
step S200, mounting at least one metal piece onto the mounting surface, wherein the metal
piece is electrically connected to the grounding pad;
step S300, forming a plastic package body that covers the semiconductor device and the metal piece;
step S400, forming an electromagnetic shielding layer that covers the plastic package body and side surfaces of the substrate;
step S500, exposing a surface of the metal piece;
step S600, mounting a grounding body to the surface of the metal piece through soldering technology.

For example, SMT (surface mount technology), mount bonding technology, or soldering technology may be used to mount the semiconductor device and the metal piece onto the mounting surface of the substrate. The semiconductor device and metal piece may be mounted onto the mounting surface in different stages or at the same time. Being mounted at the same time can reduce the number of production procedures and improve production efficiency.

Material of the metal piece includes, for example, copper or silver, and a shape of the metal piece is not limited to cuboid. The metal piece may be directly connected to the grounding pad of the substrate through soldering technology, or a conductor may be used to connect the grounding pad of the substrate. The grounding pad may be a ground soldering pad, a ground pin, or a pad or pin electrically connected to a grounding layer of the substrate.

An electromagnetic shielding layer may be formed on periphery of the plastic package body through a method such as sputtering, spraying, plating, or coating.

Grooving above the metal piece to remove a part, that is above the metal piece, of the plastic package body and a part, that is above the metal piece, the electromagnetic shielding layer, to expose a surface of the metal piece. A method for removing the part of the plastic package body and the part of the electromagnetic shielding layer includes but is not limited to laser, etching, or drilling.

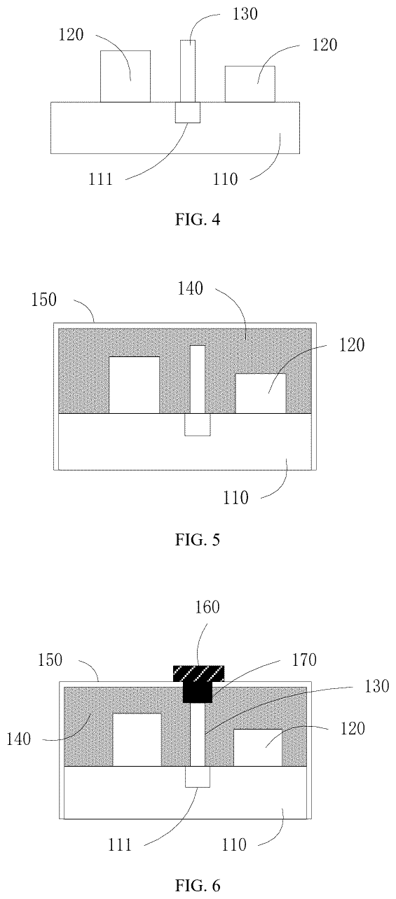

Referring to FIG. 4, through steps S100 to S200, the production of the substrate 110 is completed. The substrate 110 is provided with a grounding pad 111, and the semiconductor device 120 and the metal piece 130 are mounted on the substrate.

Referring to FIG. 5, through steps S300 to S400, the plastic package body 140 and the electromagnetic shielding layer 150 are formed.

Referring to FIG. 6, through steps S500 to S600, the grounding body 160 is connected to the metal piece 130 through the solder 170.

The grounding body includes a metal part, a metal spring, a metal wire, or the like. Tin may be dotted or solder balls may be implanted onto the surface of the metal piece, and then the grounding body may be mounted to the surface of the metal piece through soldering technology. Since the grounding body is mounted onto the surface of the metal piece through soldering technology, and the metal piece is electrically connected to the grounding pad of the substrate, compared with a traditional solution that a grounding body that is sticked to an electromagnetic shielding layer through a copper foil tape to be grounded with the substrate, this solution improves grounding reliability of the grounding body and also ensures integrity of electromagnetic shielding.

In an embodiment, the metal piece is a shielding device for electromagnetic shielding, located between semiconductor devices of a plurality of semiconductor devices. Metal pieces, together with the electromagnetic shielding layer, form a plurality of electromagnetic shielding compartments.

Some scenarios require compartment shielding. For example, a plurality of semiconductor devices is mounted onto the mounting surface, and a shielding device is mounted between the semiconductor devices that require electromagnetic shielding. A plastic package body is formed to cover all semiconductor devices and the shielding device, but the surface of the shielding device is exposed, and then an electromagnetic shielding layer is formed on the surface of the plastic package body to cover the plastic package body, the surface of the shielding device and side surfaces of the substrate. The electromagnetic shielding layer is electrically connected to the shielding device, thereby realizing the compartment electromagnetic shielding function.

The metal piece used as the shielding device may be designed based on an electronic component or area that requires electromagnetic shielding, and be inserted into a position on the substrate where electromagnetic shielding is required.

In this scenario, the metal piece used as the shielding device can also be used as a metal part soldered to the grounding body, so that there is no need to add an extra metal part and the cost is reduced.

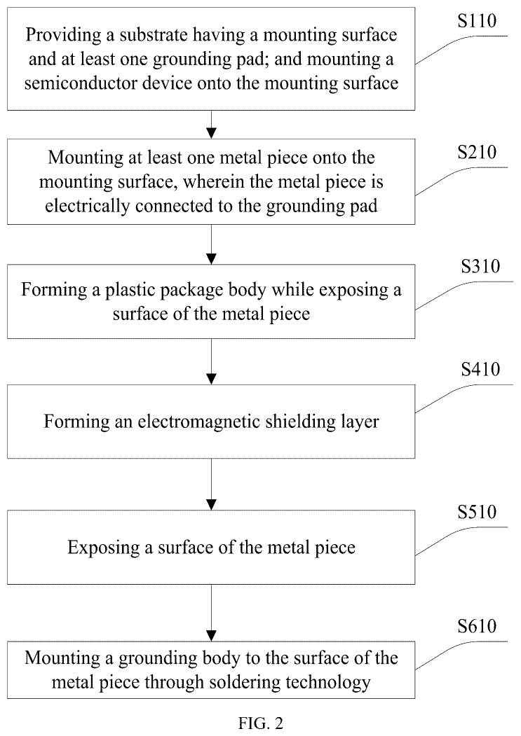

In another embodiment of the present application, as shown in FIG. 2, a method of manufacturing a semiconductor package structure includes:
step S110, providing a substrate having a mounting surface and at least one grounding pad; and mounting a semiconductor device onto the mounting surface;
step S210, mounting at least one metal piece onto the mounting surface, wherein the metal piece is electrically connected to the grounding pad;
step S310, forming a plastic package body that covers the semiconductor device and the metal piece while exposing a surface of the metal piece;
step S410, forming an electromagnetic shielding layer that covers the plastic package body, the surface of the metal piece and side surfaces of the substrate;
step S510, removing a part, that covers the surface of the metal piece, of the electromagnetic shielding layer to expose the surface of the metal piece;
step S610, mounting a grounding body to the surface of the metal piece through soldering technology.

Most of the steps in this embodiment are the same as those in the previous embodiment and will not be repeated here. The main differences lie in step S310 and step S510.

In a plastic packaging stage, there are a plurality of ways to expose the surface of the metal piece from the plastic package body:

In an embodiment, step S310 includes:
step S311, adopting a film assisted molding technology, whereby a film is affixed to the surface of the metal piece, and then covering the semiconductor device and the metal piece with plastic packaging material.

In an embodiment, step S310 includes:
step S312, firstly, forming a plastic package body covering the semiconductor device and the metal piece, then grooving above the metal piece to remove a part, that is above the metal piece, of the plastic package body to expose the surface of the metal piece.

A grooving method to remove a part of the plastic package body includes but is not limited to laser, etching, or drilling.

Step S510 includes: step S512, removing a part, that is on a bottom surface of the groove, of electromagnetic shielding layer to expose the surface of the metal piece.

In an embodiment, step S310 includes:
step S313, firstly, forming a plastic package body covering the semiconductor device and the metal piece, and then removing a part of the plastic package body by grinding or laser processes to expose the surface of the metal piece.

This method is suitable for a scenario where a height of the metal piece is greater than that of the semiconductor device.

The electromagnetic shielding layer is formed through step S410. Since the surface of the metal piece is only covered with the electromagnetic shielding layer, the surface of the metal piece can be exposed by simply removing the part of the electromagnetic shielding layer in step S510.

In an embodiment, the metal piece is a shielding device used for electromagnetic shielding. That is, the metal piece configured as a shielding device is also used as a metal part soldered to the grounding body, so that there is no need to add an extra metal part and cost is reduced.

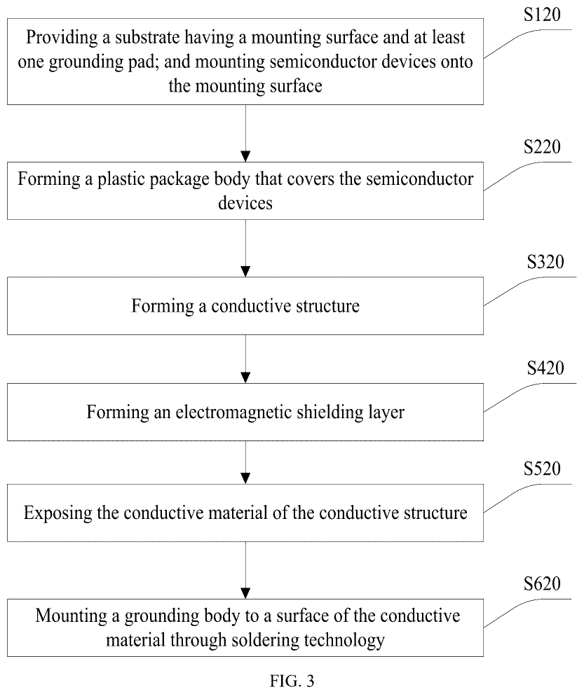

In another embodiment of the present application, as shown in FIG. 3, a method of manufacturing a semiconductor package structure includes:
step S120, providing a substrate having a mounting surface and at least one grounding pad; and mounting semiconductor devices onto the mounting surface;
step S220, forming a plastic package body that covers the semiconductor devices;
step S320, forming a groove on the plastic package body between the semiconductor devices, and filling the groove with conductive material to form a conductive structure; wherein the conductive structure is electrically connected to the grounding pad;
step S420, forming an electromagnetic shielding layer that covers the plastic package body, a surface of the conductive structure and side surfaces of the substrate;
step S520, exposing the conductive material of the conductive structure;
step S620, mounting a grounding body to a surface of the conductive material through soldering technology.

For example, the conductive material includes silver glue. In this embodiment, a groove is formed at a location where electromagnetic shielding is required. Conductive material is filled in the groove to obtain a conductive structure. The conductive structure, together with the electromagnetic shielding layer, form a compartment electromagnetic shielding structure between the semiconductor devices.

The grounding body includes a metal part, a metal spring, a metal wire, or the like. Tin may be dotted or solder balls may be implanted onto the surface of the conductive material, and then the grounding body may be mounted onto the surface of the conductive material through soldering technology.

In this scenario, the grounding body is mounted onto the surface of the conductive material in the conductive structure through soldering technology. Compared with the traditional solution that the grounding body is sticked to the electromagnetic shielding layer through the copper foil tape to be grounded with the substrate, this solution improves reliability of grounding connection between the grounding body and the substrate.

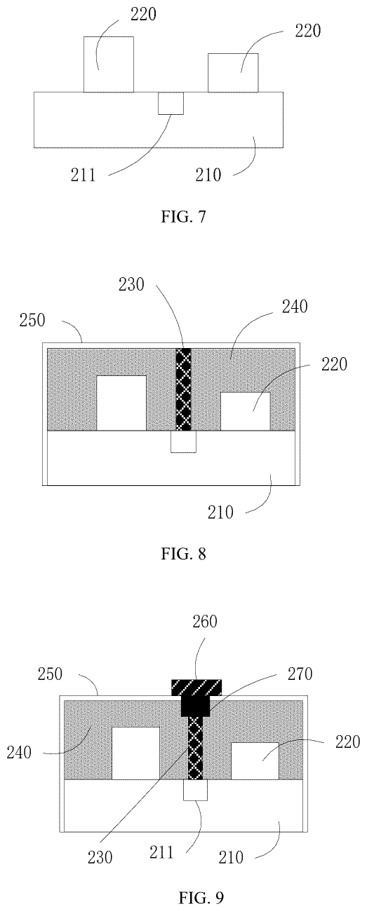

Referring to FIG. 7, through step S120, the production of the substrate 210 is completed. The substrate 210 is provided with a grounding pad 211 and the semiconductor device 220 is mounted thereon.

Referring to FIG. 8, through steps S220 to S420, a plastic package body 240, a conductive structure 230 and an electromagnetic shielding layer 250 are formed. The conductive structure 230 is electrically connected to the grounding pad 211.

Referring to FIG. 9, through steps S520 to S620, the grounding body 260 is connected to the conductive material of the conductive structure 230 through the solder 270.

In an embodiment, step S520 includes: grooving above the conductive structure to a certain depth, and removing a part, that is above the surface of the conductive structure, of the electromagnetic shielding layer to expose the conductive material of the conductive structure.

In an embodiment, in the filling procedure of step S320, a certain depth of the groove is not filled with conductive material. In this way, in step S520, the electromagnetic shielding layer on a bottom surface of the groove can be directly removed to expose the conductive material of the conductive structure.

In an embodiment of the present application, as shown in FIG. 6, a semiconductor package structure includes:
a substrate 110, having a mounting surface and at least one grounding pad 111;
a semiconductor device 120, mounted on the mounting surface;
a metal piece 130, mounted on the mounting surface, and the metal piece is electrically connected to the grounding pad;
a plastic package body 140, configured to cover the semiconductor device and the metal piece except for a surface of the metal piece;
an electromagnetic shielding layer 150, configured to cover the plastic package body and side surfaces of the substrate;
a grounding body 160, connected to the metal piece 130 through solder 170.

The semiconductor package structure may be manufactured by the method of manufacturing a semiconductor package structure of the above-mentioned embodiment. By soldering the grounding body to the metal piece, the grounding reliability of the grounding body is improved and the integrity of the electromagnetic shielding is ensured.

In another embodiment of the present application, as shown in FIG. 9, a semiconductor package structure includes:
a substrate 210, having a mounting surface and at least one grounding pad 211;
a plurality of semiconductor devices 220, mounted on the mounting surface;
a plastic package body 240, configured to cover the semiconductor devices;
a conductive structure 230, filled with conductive material and located between the semiconductor devices; wherein the conductive structure 230 is electrically connected to the grounding pad 211;
an electromagnetic shielding layer 250, configured to cover the plastic package body and side surfaces of the substrate, and electrically connected to the conductive structure 230;
a grounding body 260, connected to the conductive material of the conductive structure 230 through solder 270.

The semiconductor package structure may be manufactured by the method of manufacturing a semiconductor package structure of the above-mentioned embodiment. By soldering the grounding body to the conductive material, the grounding reliability of the grounding body is improved and the integrity of the electromagnetic shielding is ensured.

It should be noted that the above embodiments can be freely combined as needed. The above are only some embodiments of the present application. It should be pointed out that for those of ordinary skill in the art, several improvements and modifications can be made without departing from the principles of the present application. These improvements and modifications should also be regarded as within the protection scope of the present application.

What is claimed is:

1. A method of manufacturing a semiconductor package structure, comprising:
providing a substrate, wherein the substrate has a mounting surface and a grounding pad;
mounting a first semiconductor device onto the mounting surface;
mounting a metal piece onto the mounting surface, wherein the metal piece is electrically connected to the grounding pad;
forming a plastic package body, wherein the plastic package body covers the first semiconductor device and the metal piece;
forming an electromagnetic shielding layer, wherein the electromagnetic shielding layer covers the plastic package body and side surfaces of the substrate; and
mounting a grounding body to a surface of the metal piece through soldering, wherein the surface of the metal piece is exposed from the plastic package body and the electromagnetic shielding layer.

2. The method according to claim 1, further comprising:
grooving above the metal piece to remove a part of the plastic package body and a part of the electromagnetic shielding layer, to expose the surface of the metal piece, wherein the part of the plastic package body is above the metal piece, and the part of the electromagnetic shielding layer is above the metal piece.

3. The method according to claim 1, further comprising:
grooving, after forming the plastic package body, above the metal piece to remove a part of the plastic package body to expose the surface of the metal piece, wherein the part of the plastic package body is above the metal piece, and the electromagnetic shielding layer is formed to cover the plastic package body, the surface of the metal piece and the side surfaces of the substrate; and
removing a part of the electromagnetic shielding layer to expose the surface of the metal piece, wherein the part of the electromagnetic shielding layer covers the surface of the metal piece.

4. The method according to claim 1, wherein the metal piece is used for electromagnetic shielding.

5. The method according to claim 1, wherein the electromagnetic shielding layer is formed by sputtering, spraying, plating, or coating.

6. A method of manufacturing a semiconductor package structure, comprising:
providing a substrate, wherein the substrate has a mounting surface and a grounding pad;
mounting a first semiconductor device onto the mounting surface;
forming a plastic package body, wherein the plastic package body covers the first semiconductor device;
forming a groove on the plastic package body, wherein the groove is connected to the grounding pad;
filling the groove with a conductive material to form a conductive structure;
forming an electromagnetic shielding layer, wherein the electromagnetic shielding layer covers the plastic package body, a surface of the conductive material, and side surfaces of the substrate;
exposing the surface of the conductive material; and
mounting a grounding body to the surface of the conductive material through soldering.

7. The method according to claim 6, wherein the conductive material is exposed by grooving above the conductive structure to remove a part of the electromagnetic shielding layer, wherein the part of the electromagnetic shielding layer is above the surface of the conductive material.

8. A semiconductor package structure, comprising:
a substrate, having a mounting surface and a grounding pad;
a first semiconductor device, mounted on the mounting surface;
a plastic package body, configured to cover the first semiconductor device;
an electromagnetic shielding layer, configured to cover the plastic package body and side surfaces of the substrate;
a conductive part, located in the plastic package body and electrically connected to the grounding pad, wherein a surface of the conductive part is exposed from the plastic package body and the electromagnetic shielding layer; and
a grounding body, mounted to the surface of the conductive part through a soldering part.

9. The method according to claim 1, further comprising:
mounting a second semiconductor device onto the mounting surface, wherein the plastic package body covers the second semiconductor device and the metal piece, and the metal piece is located between the first semiconductor device and the second semiconductor device.

10. The method according to claim 6, wherein the conductive structure is used for electromagnetic shielding.

11. The method according to claim 6, wherein the electromagnetic shielding layer is formed by sputtering, spraying, plating, or coating.

12. The method according to claim 6, further comprising:
mounting a second semiconductor device onto the mounting surface, wherein the plastic package body covers the second semiconductor device, and the groove is formed between the first semiconductor device and the second semiconductor device.

13. The semiconductor package structure according to claim 8, wherein the conductive part comprises:
a metal piece, mounted on the mounting surface.

14. The semiconductor package structure according to claim 8, wherein the conductive part comprises:
a conductive structure, formed in the plastic package body, and filled with a conductive material;
wherein the conductive material is electrically connected to the grounding pad, a surface of the conductive material is exposed from the plastic package body and the electromagnetic shielding layer, and the grounding body is mounted to the surface of the conductive material through the soldering part.

15. The semiconductor package structure according to claim 8, further comprising:
a second semiconductor device, mounted on the mounting surface, wherein the plastic package body covers the second semiconductor device;
wherein the conductive part is located between the first semiconductor device and the second semiconductor device.

16. The semiconductor package structure according to claim 8, wherein the conductive part is used for electromagnetic shielding.
